(19) United States
(12) Patent Application Publication
(10) Pub. No.: US 2008/0096475 A1
(43) Pub. Date: Apr. 24, 2008

(54) Polishing Composition and Polishing Method

(76) Inventor: Kazuaki Yoshida, Oita (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/593,147

(22) PCT Filed: Mar. 3, 2005
(86) PCT No.: PCT/JP05/03627

§ 371 Date: Aug. 20, 2007

(30) Foreign Application Priority Data
Mar. 19, 2004 (JP) 2004-080183

(51) Int. Cl. C09K 3/14; B24B 37/00; H01L 21/304

(52) U.S. Cl. 451/60; 51/308

(57) ABSTRACT

The present invention aims to improve the polishing rate during the polishing process of semiconductor substrates, hard disk substrates or the like by using a polishing composition containing silica particles, water, a basic substance and an inorganic salt, and by a polishing method using such a polishing composition.

This polishing composition can be produced by mixing silica particles, water, a basic substance and an inorganic salt, and it is also obtained by adding an inorganic salt into a conventionally known alkaline polishing composition containing silica particles.

As the inorganic salt, there is used an alkali metal salt or an ammonium salt such as KCl, K₂SO₄, KNO₃, NaCl, Na₂SO₄, NaNO₃, NH₄Cl, NH₄NO₃, and (NH₄)₂S0₄.

A polishing composition, wherein silica particles do not agglomerate when an inorganic salt is added, can improve the polishing rate significantly.

### TECHNICAL FIELD

The present invention relates to a polishing composition used for polishing semiconductor substrates, hard disk substrates, and the like, and to a polishing method in which such composition material is used. Specifically, the present invention relates: to a polishing composition that has an improved polishing rate and includes silica particles, water, a basic material, and an inorganic salt; and to a polishing method in which this composition material is used.

### BACKGROUND ART

In recent years, semiconductor devices and hard disks have become markedly smaller, have acquired increased capacity, and have undergone other remarkable increases in functionality. For this reason, hard disk substrates and silicon wafers, which are semiconductor device substrates, are required to have extremely flat, damage-free surfaces, and distortion-free mirror polishing and planarization have been widely employed. So-called mechanical-chemical polishing (CMP) is used to perform such surface treatments. This method involves the use of a nonwoven fabric having a unique structure (polishing pad) and a polishing liquid (slurry) obtained by suspending silica particles in an alkaline solution having a pH of around 10.

A general outline of such a polishing device is shown in FIG. 1. Polishing is performed while a slurry 13 (the slurry feed part is not shown) is continuously fed to an interface between a polishing pad 11 and a wafer 12. The polishing pad 11 is affixed to a polishing plate 14, and the wafer 12 is affixed to a wafer carrier 15. The polishing plate 14 and wafer carrier 15 are rotated while a difference in their relative speeds is created, and polishing pressure is applied between the polishing plate 14 and the wafer 12.

Silica particles readily aggregate in aqueous solutions, and are therefore usually kept in an alkaline solution. Silica particles are also used as an abrasive while kept dispersed in an alkali aqueous solution. For example, 3900RS (trade name; manufactured by Kabushiki Kaisha Fujimi Corporation), ILD-1300 (trade name; manufactured by Rodel Nitta Kabushiki Kaisha), and other polishing liquids are microparticulate silica alkaline polishing liquids obtained by adding silica particles to an ammonia solution. Another example of a polishing liquid obtained by suspending silica particles in an alkaline solution is disclosed in Patent Document 1.

Various types of silica particles that differ in manufacturing method and shape are used as abrasives. However, in terms of machining the substrate material to an extremely flat, damage-free surface, colloidal silica produced from alkoxysilane is significantly better than materials such as colloidal silica for which fumed silica and aqueous glass are used as starting materials. However, colloidal silica has a drawback in that the polishing rate is low.

When an abrasive has a low polishing rate, the scope of application thereof is limited to the touch polishing used to remove scratches during the final polishing of a silicon wafer, and to the use as an auxiliary material in some operations involved in the polishing of metal films on semiconductor substrates. Due to such circumstances, improvements in the polishing rate of silica particles are strongly needed.

Polishing liquids in which silica particles are added as an abrasive are typically used in an alkaline state. The reason that the alkaline state is maintained is that a higher polishing rate can be obtained. By adding ammonia to the polishing liquid and examining the polishing rate of a silicon wafer, it can be confirmed that the higher the alkalinity, the higher the polishing rate. This is one means for improving the polishing rate of the silica particles, and it is employed to alkalize commercial polishing liquids as well. However, because silica particles tend to be readily dissolved in alkaline aqueous solutions having a pH of 9 or higher, an actual polishing liquid cannot be made to have an unreasonably high pH. In addition, when the alkalinity is high, disposal of spent polishing liquid becomes problematic. In view of these factors, the inventors arrived at the present invention as a result of extensive research on methods for improving polishing rate without the addition of a large amount of alkalis.

Japanese Patent Application 2002-3717811

### SUMMARY OF THE INVENTION

The following are used as an abrasive in the present invention:

(1) a polishing composition comprising silica particles, water, a basic material, and an inorganic salt;

(2) a polishing composition comprising silica particles, water, a basic material, and an inorganic salt, wherein the silica particles do not aggregate after the inorganic salt is added;

(3) a polishing composition in which the inorganic salt is an alkali metal salt or an ammonium salt.

The present invention also provides:

(4) a polishing method involving the use of the above-mentioned compositions.

An improvement in polishing rate is thereby achieved.

The polishing composition of the present invention is readily obtained by mixing silica particles, water, a basic material, and an inorganic salt. However, the present invention is also readily produced by adding an inorganic salt to a pre-prepared polishing composition comprising silica particles, water, and a basic material. Therefore, the polishing composition of the present invention can also be produced by adding an inorganic salt to a commercially available polishing composition that includes silica particles, water, and a basic material. This method for producing a polishing composition makes it possible: to eliminate instability arising from aggregation of the silica particles within the composition, changes in the particle diameters, and variation in the polishing rate; and to retain stability for an extended period of time. In addition, the polishing composition of the present invention comprises silica particles, water, a basic material, and an inorganic salt, but may also include other wetting agents or other materials usually included in polishing compositions.

A comparison made between a conventionally known polishing composition that comprises silica particles, water, and a basic material and the present invention, which is obtained by adding an inorganic salt to such a polishing composition, reveals that the polishing composition of the present invention exhibits a markedly higher polishing rate. An even higher polishing rate is exhibited when silica particles do not aggregate after the inorganic salt has been added to a polishing composition comprising silica particles, water, and a basic material. This is because aggregation of the silica particles entails a decrease in the polishing rate. The “aggregation of particles” hereunder refers to the massing together or clumping of the silica particles so that the diameters of the particles increase, and it is observed as the formation of precipitates, cloudiness in the solution, and the like. This phenomenon occurs, e.g., when an excessively large amount of inorganic salt is added. Aggregation also occurs when a small amount of an alkaline-earth metal salt is added.

Silica particles produced through any manufacturing method and of any shape may be used in the polishing composition of the present invention. However, colloidal silica is preferable to fumed silica. This is due to that fumed silica is synthesized in high-temperature flames, and therefore the particles of fumed silica often melt together so that the surface is no longer smooth. Accordingly, a material that is molten at a high temperature may be used, provided the surface thereof is smooth. Examples of preferred silica particles include spherical silica obtained by re-melting fumed silica and then forming large particles.

There are no particular restrictions on the particle diameter of the silica particles used in the polishing composition of the present invention, but the diameter is preferably between 5 and 500 nm, and are more preferably between 20 and 200 nm. If the particle diameter of the silica is too small, the silica will become embedded in the fine unevenness of the pad during polishing, preventing polishing performance from being exhibited. On the other hand, if the particle diameter is too large, the silica particles within the polishing composition will readily precipitate and not be able to reach the polishing interface between the wafer and the polishing pad.

The polishing composition of the present invention includes a basic material and is therefore alkaline. This alkalinity is preferably in a pH range of 7.5 to 12.0. The pH is more preferably in a range of from 8.0 to 10.5. If the pH is in a range of from 8.0 to 10.5, the addition of an inorganic salt yields a dramatic improvement in the polishing rate. In the region below a pH of 7.5, the slurry is less stable. In the region above a pH of 12.0, the silica particles dissolve and the particle diameter decreases. The reason that the polishing composition of the present invention comprises a basic material is that a polishing composition that comprises silica particles, water, and a basic material is easy to store, and that the polishing composition of the present invention can be readily produced when an inorganic salt is added to such a polishing composition. There are no particular restrictions to the basic materials that can be used in the present invention, but chemical compounds that do not cause the silica particles to aggregate are preferred. Examples of such basic materials include: alkali metal hydroxides such as NaOH, KOH; and NH₄OH (aqueous ammonia). Amines such as tetramethyl ammonium hydroxide (TMAH) can also be used. KOH or NH₄OH (aqueous ammonia) are preferable.

The amount of silica particles included in the polishing composition of the present invention is preferably 0.1 to 5.0%, and more preferably 0.2 to 1.0%, based on the weight of the entire polishing material. If the amount of silica particles is too high, the particles will readily aggregate and cause the polishing rate to decrease. Examples of the inorganic salts of the present invention include alkali metal salts and ammonium salts such as KCl, K₂SO₄, KNO₃, NaCl, Na₂SO₄, NaNO₃, NH₄Cl, NH₄NO₃, and (NH₄)₂SO₄, and one or more can be selected from among these examples.

The polishing composition preferably has a higher inorganic salt content because a larger amount leads to a better polishing rate. However, if the inorganic salt content is too high, the silica particles will readily aggregate, causing the polishing rate to decrease. The inorganic salt content is preferably within a range of 1.0 mol or less per one liter of polishing composition. The inorganic salt content is more preferably within a range of 0.5 mol or less per one liter of polishing composition. The preferred range will vary depending on the type of inorganic salt, the pH of the polishing composition, and other such factors.

The polishing method of the present invention is performed using the above-described polishing composition. The polishing is performed by so-called mechanical-chemical polishing (CMP), which involves the use of a nonwoven fabric with a unique structure (polishing pad) and a polishing liquid (slurry). A simple outline of such a polishing device is shown in FIG. 1. Polishing is performed while a slurry 13 (the slurry feed part is not shown) is continuously fed to an interface between a polishing pad 11 and a wafer 12. The polishing pad 11 is affixed to a polishing plate 14, and the wafer 12 is affixed to a wafer carrier 15. The polishing plate 14 and wafer carrier 15 are rotated while a difference in their relative speeds is created, and polishing pressure is applied between the polishing plate 14 and the wafer 12.

### BRIEF DESCRIPTION OF THE DRAWINGS

FIG. 1 is a descriptive diagram of a polishing device.

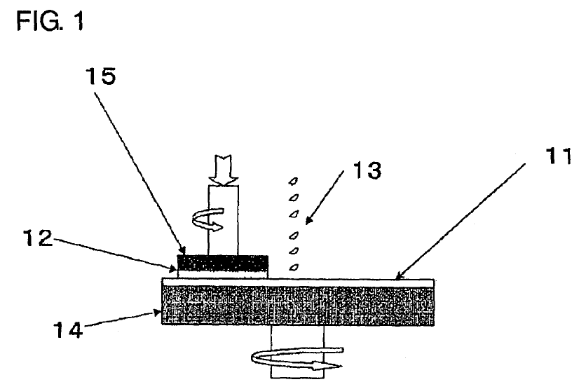

### BEST MODE FOR CARRYING OUT THE INVENTION

Embodiments of the present invention are described hereunder. However, a general outline of the methods of implementing the present invention will be described before the examples of the present invention are discussed.

Polishing was performed with the aid of the polishing composition under the following polishing conditions using a Daiyarap ML-150P polishing machine (manufactured by Maruto Instrument Co.), an EXP-2 polishing pad (manufactured by Fujibo), and a two-inch silicon wafer.

Polishing composition feeding rate: 20 ml/min

Polishing pressure: 0.180 kgf/cm²

Polishing rate: 80 rpm

Polishing time: 30 minutes

The weight of the silicon wafer was measured before and after polishing, and the polishing rate was calculated from the amount of weight lost. A polishing rate of a reference polishing composition acting as a reference for evaluation was set as 100%, and values relative thereto were used to display the polishing rate of the tested polishing compositions.

The method for manufacturing the polishing composition shall next be described. First, the reference polishing composition comprising silica particles and a basic material was prepared by adding ammonia, hydroxyethyl cellulose (HEC), purified water, diethylene glycol, and the like to silica particles, which serve as an abrasive. The composition comprised 0.5 wt % of silica having an ammonia average particle diameter of 46 nm, 250 wt. ppm of ammonia, 175 wt. ppm of Fujichemi HEC CF-X, and 65 wt. ppm of diethylene glycol. The polishing composition of the present invention that comprises an inorganic salt was prepared by adding the inorganic salt to the reference polishing composition.

### EXAMPLES 1, 2, 3, AND 4

The salts shown in table 1 were added to the reference polishing composition in an amount corresponding to 0.36 mol/L to prepare the polishing compositions of examples 1, 2, 3, and 4. The polishing rates of the polishing compositions were measured by the above-described method, yielding the results shown in Table 1. It can be understood from Table 1 that each of the polishing compositions of the present invention to which an inorganic salt was added exhibited higher polishing rates than the reference polishing composition, which did not have inorganic salts.

TABLE 1
Examples 1 through 4

| | | Polishing rate | |
|---|---|---|---|
| | Type of Salt | (%) | Remarks (pH) |
| Example 1 | Potassium | 341 | 9.7 |
| | chloride | | |
| Example 2 | Potassium | 322 | 9.8 |
| | sulfate | | |
| Example 3 | Sodium | 256 | 9.8 |
| | chloride | | |
| Example 4 | Sodium nitrate | 234 | 9.8 |

When sodium chloride was added, the silica particles began to aggregate and precipitate soon afterwards. The polishing rate of the slurry having these precipitates was measured in the same manner described above, and was found to be 168%. A decrease in polishing rate due to aggregation was observed; however, it was found that the polishing rate increased, even in such cases, due to the inclusion of an inorganic salt.

### EXAMPLES 5 AND 6

0.14 mol/L of each of the salts shown in Table 2 was added to the reference polishing composition to prepare the polishing compositions of examples 5 and 6. The polishing rates of the polishing compositions were measured by the above-described method, resulting in the values shown in Table 2. It can be understood from Table 2 that each of the polishing compositions of the present invention to which an inorganic salt was added had higher polishing rates than the reference polishing composition, which did not include inorganic salts.

TABLE 2
Examples 5 and 6

| | | Polishing rate | |
|---|---|---|---|
| | Type of Salt | (%) | Remarks (pH) |
| Example 5 | Potassium | 228 | 9.7 |
| | chloride | | |
| Example 6 | Ammonium | 150 | 8.3 |
| | chloride | | |

### EXAMPLE 7 AND COMPARATIVE EXAMPLES 1 AND 2

0.07 mol/L of each of the salts shown in Table 3 was added to the reference polishing composition to prepare the polishing compositions of example 7 and comparative examples 1 and 2. The polishing rates of the polishing compositions were measured by the above-described method, resulting in the values shown in Table 3. It can be understood from example 7 in Table 3 that the polishing composition of the present invention has a higher polishing rate than the reference polishing composition, which did not include inorganic salts, even if only a small amount of an inorganic salt is added. In addition, alkaline earth-metal salts were added in comparative examples 1 and 2, but the silica particles began to aggregate and precipitate soon after the salts were added. For this reason, the polishing rate could not be measured.

TABLE 3
Example 7 and comparative examples 1 and 2

| | | Polishing rate | |
|---|---|---|---|
| | Type of salt | (%) | Remarks (pH) |
| Example 7 | Potassium | 185 | 9.7 |
| | chloride | | |
| Comparative | Calcium | Not measurable | Precipitation |
| Example 1 | chloride | | present, 10.0 |
| Comparative | Magnesium | Not measurable | Precipitation |
| Example 2 | chloride | | present, 9.8 |

### EXAMPLES 8 AND 9, AND COMPARATIVE EXAMPLE 3

0.29 mol/L of aqueous ammonia and 0.36 mol/L of each of the salts shown in table 4 were added to the reference polishing composition to prepare the polishing compositions of comparative example 3 and examples 8 and 9. The polishing rates of the polishing compositions were measured by the above-described method, resulting in the values shown in Table 4. It can be understood from Table 4 that each of the polishing compositions of the present invention to which an inorganic salt was added also had higher polishing rates than the reference polishing compositions, which did not have inorganic salts. Additionally, in comparative example 3, ammonia was added to the reference polishing composition to raise the pH. The polishing rate was increased by raising the pH. Example 8 and 9 are polishing compositions of the present invention obtained by adding not only ammonia, but also inorganic salts. The polishing rate was even higher than when only ammonia was added. However, this increase was lower than those observed in the low-pH examples 1 and 4.

TABLE 4
Examples 8 and 9, and comparative example 3

| | | Polishing rate | |
|---|---|---|---|
| | Type of salt | (%) | Remarks (pH) |
| Example 8 | Potassium | 207 | 11.3 |
| | chloride | | |
| Example 9 | Sodium nitrate | 177 | 11.4 |
| Comparative | None | 168 | 11.1 |
| example 3 | | | |

### EXAMPLE 10

0.14 mol/L of potassium chloride and 0.14 mol/L of ammonium chloride were added to the reference polishing composition to yield the polishing composition of the present invention having a pH of 8.3. The polishing rate of this polishing composition was measured by the above-described method, and was found to be 154%. The polishing rate was higher than in a polishing composition to which no inorganic salt is added, even when two types of inorganic salts are added.

### EXAMPLE 11

0.71 mol/L of potassium chloride was added to the reference polishing composition to prepare the polishing composition of the present invention having a pH of 9.8. Silicon particle deposits formed in this polishing composition. The composition was used while being stirred, and the polishing rate thereof was measured by the above-described method. The result was a polishing rate of 171%. The polishing rate was higher than in a polishing composition to which no inorganic salt was added. However, the polishing rate was lower than that of examples 1, 5, 7, and 8 in which precipitation did not occur.

### COMPARATIVE EXAMPLE 4

A polishing composition was prepared by using spherical silica particles that had an average particle diameter of 340 nm and that were prepared by heating fumed silica to increase the particle diameter. The manufacturing method involved adding ammonia, hydroxyethyl cellulose (HEC), and purified water to silica particles. This polishing composition included 0.5 wt % of silica, 2250 wt. ppm of ammonia, and 175 wt. ppm of Fujichemi HEC CF-X. The polishing rate of this polishing composition was measured by the above-described method, and was found to be 61%. The polishing rate of this polishing composition was comparatively lower than in the reference polishing composition, but this was due to the large particle diameter.

### EXAMPLE 12

0.36 mol/L of sodium chloride was added to the polishing composition of comparative example 4 to prepare the polishing composition of the present invention. The polishing rate of this polishing composition was measured by the above-described method, and was found to be 86%. When compared with the polishing composition of comparative example 4 to which no inorganic salt was added, the polishing rate of this polishing composition increased by 141%.

### INDUSTRIAL APPLICABILITY

The polishing composition of the present invention is superior to conventional polishing compositions that comprise silica particles, water, and a basic material in having a dramatically better polishing rate; being more readily prepared; and causing little burden in terms of disposing of the high alkaline liquid waste. This polishing composition can be widely used on semiconductor substrates, hard disk substrates, and other such articles. The polishing rate is improved by using this polishing composition.

1. A polishing composition comprising:
silica particles;
water;
a basic material; and
an inorganic salt such as alkali metal salt and ammonium salt.

2. The polishing composition of claim 1, wherein an alkali metal salt or an ammonium salt such as KCl, K₂SO₄, KNO₃, NaCl, Na₂SO₄, NaNO₃, NH₄Cl, NH₄NO₃, and (NH₄)₂SO₄ is used as the inorganic salt.

3. The polishing composition of claim 2, wherein the silica particles do not aggregate soon after the inorganic salt is added to the composition.

4. A polishing method for performing polishing while continuously feeding a polishing composition between a polishing pad and a polishing sample, wherein the polishing composition of claim 1, 2, or 3 is used as the polishing composition.
